(19) United States
(12) Patent Application Publication
(10) Pub. No.: US 2007/0085140 A1
(43) Pub. Date: Apr. 19, 2007

(54) One transistor memory cell having strained electrically floating body region, and method of operating same

(76) Inventor: Cedric Bassin, Tramelan (CH)

Correspondence Address: Neil A. Steinberg, 2665 Marine Way, Suite 1150, Mountain View, CA, 94043, US

(21) Appl. No.: 11/580,169

(22) Filed: Oct. 12, 2006

Related U.S. Application Data
(60) Provisional application No. 60/728,060, filed on Oct. 19, 2005.

(51) Int. Cl. H01L 27/12

(52) U.S. Cl. 257/353

(57) ABSTRACT

A semiconductor memory cell comprising a transistor having (i) an electrically floating body region and (ii) semiconductor source, drain and/or body regions that are “locally” or “globally” under mechanical strain (for example, strain introduced via tensile or compressive forces). The semiconductor memory cell includes (1) a first data state which corresponds to a first charge in the electrically floating body region of the transistor of the memory cell, and (2) a second data state which corresponds to a second charge in the electrically floating body region of the transistor of the memory cell. The semiconductor memory cell may comprise a portion of an integrated circuit device, for example, logic device (such as, a microcontroller or microprocessor) or a portion of a memory device (such as, a discrete memory). A plurality of such memory cells may be arranged to form a memory cell array.

### RELATED APPLICATIONS

This application claims priority to (1) U.S. Provisional Application Ser. No. 60/728,060, entitled “One Transistor Memory Cell having Mechanically Strained Electrically Floating Body Region, and Method of Operating Same”, filed Oct. 19, 2005; the contents of thereof are incorporated by reference herein in their entirety.

### BACKGROUND

The inventions relate to a semiconductor memory cell, array, architecture and device, and techniques for controlling and/or operating such cell, array and device; and more particularly, in one aspect, to a dynamic random access memory (“DRAM”) cell, array, architecture and device, wherein the memory cell includes an electrically floating body wherein an electrical charge is stored therein.

There is a continuing trend to employ and/or fabricate advanced integrated circuits using techniques, materials and devices that improve performance, reduce leakage current and enhance overall scaling. Semiconductor-on-Insulator (SOI) is a material in which such devices may be fabricated or disposed on or in (hereinafter collectively “on”). Such devices are known as SOI devices and include, for example, partially depleted (PD), fully depleted (FD) devices, multiple gate devices (for example, double or triple gate), and Fin-FET.

One type of dynamic random access memory cell is based on, among other things, the electrically floating body effect of SOI transistors. (See, for example, U.S. Pat. No. 6,969,662, incorporated herein by reference). In this regard, the dynamic random access memory cell may consist of a PD or a FD SOI transistor (or transistor formed in bulk material/substrate) on having a channel, which is disposed adjacent to the body and separated therefrom by a gate dielectric. The body region of the transistor is electrically floating in view of the insulation layer (or non-conductive region, for example, in a bulk-type material/substrate) disposed beneath the body region. The state of memory cell is determined by the concentration of charge within the body region of the SOI transistor.

With reference to FIGS. 1A, 1B and 1C, in one embodiment, semiconductor DRAM array 10 includes a plurality of memory cells 12 each consisting of transistor 14 having gate 16, body region 18, which is electrically floating, source region 20 and drain region 22. The body region 18 is disposed between source region 20 and drain region 22. Moreover, body region 18 is disposed on or above region 24, which may be an insulation region (for example, in an SOI material/substrate) or non-conductive region (for example, in a bulk-type material/substrate). The insulation or non-conductive region 24 may be disposed on substrate 26.

Data is written into or read from a selected memory cell by applying suitable control signals to a selected word line(s) 28, a selected source line(s) 30 and/or a selected bit line(s) 32. In response, charge carriers are accumulated in or emitted and/or ejected from electrically floating body region 18 wherein the data states are defined by the amount of carriers within electrically floating body region 18. Notably, the entire contents of the '662 Patent, including, for example, the features, attributes, architectures, configurations, materials, techniques and advantages described and illustrated therein, are incorporated by reference herein.

The memory cell 12 of DRAM array 10 operates by accumulating in or emitting/ejecting majority carriers (electrons or holes) 34 from body region 18. (See, for example, the N-channel transistor in FIGS. 2A and 2B). In this regard, conventional write techniques may accumulate majority carriers (in this example, “holes”) 34 in body region 18 of memory cells 12 by, for example, impact ionization near source region 20 and/or drain region 22. (See, FIG. 2A). The majority carriers 30 may be emitted or ejected from body region 18 by, for example, forward biasing the source/body junction and/or the drain/body junction. (See, FIG. 2B).

Notably, for at least the purposes of this discussion, logic high or logic “1” corresponds to, for example, an increased concentration of majority carries in the body region relative to an unprogrammed device and/or a device that is programmed with logic low or logic “0”. In contrast, logic low or logic “0” corresponds to, for example, a reduced concentration of majority carries in the body region relative to an unprogrammed device and/or a device that is programmed with logic high or logic “1”.

In one conventional technique, the memory cell is read by applying a small bias to the drain of the transistor as well as a gate bias which is above the threshold voltage of the transistor. In this regard, in the context of memory cells employing N-type transistors, a positive voltage is applied to one or more word lines 28 to enable the reading of the memory cells associated with such word lines. The amount of drain current is determined/affected by the charge stored in the electrically floating body region of the transistor. As such, conventional reading techniques sense the amount of the channel current provided/generated in response to the application of a predetermined voltage on the gate of the transistor of the memory cell to determine the state of the memory cell; a floating body memory cell may have two or more different current states corresponding to two or more different logical states (for example, two different current conditions/states corresponding to the two different logical states: “1” and “0”).

In short, conventional writing programming techniques for memory cells having an N-channel type transistor often provide an excess of majority carriers by channel impact ionization (see, FIG. 3A) or by band-to-band tunneling (gate-induced drain leakage “GIDL”) (see, FIG. 3B). The majority carrier may be removed via drain side hole removal (see, FIG. 4A), source side hole removal (see, FIG. 4B), or drain and source hole removal, for example, using the back gate pulsing (see, FIG. 4C).

The memory cell 12 having electrically floating body transistor 14 may be programmed/read using other techniques including techniques that may, for example, provide lower power consumption relative to conventional techniques. For example, memory cell 12 may be programmed, read and/or controlled using the techniques and circuitry described and illustrated in U.S. Non-Provisional patent application Ser. No. 11/509,188, filed on Aug. 24, 2006, and entitled “Memory Cell and Memory Cell Array Having an Electrically Floating Body Transistor, and Methods of Operating Same” (hereinafter “the '118 Application”), which is incorporated by reference herein. In one aspect, the '188 Application is directed to programming, reading and/or control methods which allow low power memory programming and provide larger memory programming window (both relative to at least the conventional programming techniques).

With reference to FIG. 5, in one embodiment, the '118 Application employs, writes or programs a logic “1” or logic high using control signals (having predetermined voltages, for example, Vg=0v, Vs=0v, and Vd=3v) which are applied to gate 16, source region 20 and drain region 22 (respectively) of transistor 14 of memory cell 12. Such control signals induce or cause impact ionization and/or the avalanche multiplication phenomenon (FIG. 5). The predetermined voltages of the control signals, in contrast to the conventional method program or write logic “1” in the transistor of the memory cell via impact ionization and/or avalanche multiplication in the electrically floating body. In one embodiment, it is preferred that the bipolar transistor current responsible for impact ionization and/or avalanche multiplication in the floating body is initiated and/or induced by a control pulse which is applied to gate 16. Such a pulse may induce the channel impact ionization which increases the floating body potential and turns on the bipolar current. An advantage of the described method is that larger amount of the excess majority carriers is generated compared to other techniques.

Further, with reference to FIG. 6, when writing or programming logic “0” in transistor 14 of memory cell 12, in one embodiment of the '118 Application, the control signals (having predetermined voltages (for example, Vg=1.5v, Vs=0v and Vd=0v) are different and, in at least one embodiment, higher than a holding voltage (if applicable)) are applied to gate 16, source region 20 and drain region 22 (respectively) of transistor 14 of memory cell 12. Such control signals induce or provide removal of majority carriers from the electrically floating body of transistor 14. In one embodiment, the majority carriers are removed, eliminated or ejected from body region 18 through source region 20 and drain region 22. (See, FIG. 6). In this embodiment, writing or programming memory cell 12 with logic “0” may again consume lower power relative to conventional techniques.

When memory cell 12 is implemented in a memory cell array configuration, it may be advantageous to implement a “holding” operation for certain memory cells 12 when programming one or more other memory cells 12 of the memory cell array to enhance the data retention characteristics of such certain memory cells 12. The transistor 14 of memory cell 12 may be placed in a “holding” state via application of control signals (having predetermined voltages) that are applied to gate 16 and source region 20 and drain region 22 of transistor 14 of memory cell 12. In combination, such control signals provide, cause and/or induce majority carrier accumulation in an area that is close to the interface between gate dielectric 32 and electrically floating body region 18. (See, FIG. 7). In this embodiment, it may be preferable to apply a negative voltage to gate 16 where transistor 14 is an N-channel type transistor.

With reference to FIG. 8, in one embodiment of the '118 Application, the data state of memory cell 12 may be read and/or determined by applying control signals (having predetermined voltages, for example, Vg=−0.5v, Vs=3v and Vd=0v) to gate 16 and source region 20 and drain region 22 of transistor 14. Such signals, in combination, induce and/or cause the bipolar transistor current in those memory cells 12 storing a logic state “1”. For those memory cells that are programmed to a logic state “0”, such control signals do not induce and/or cause a considerable, substantial or sufficiently measurable bipolar transistor current in the cells programmed to “0” state. (See, the '118 Application, which, as noted above, is incorporated by reference).

### SUMMARY OF THE INVENTIONS

There are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

In one aspect, the present inventions are directed to an integrated circuit (for example, a logic or discrete memory device), disposed in or on a semiconductor region or layer which resides on or above a non-conducting region or layer of a substrate (for example, a semiconductor-on-insulator substrate or a bulk-type substrate). In this aspect, the integrated circuit includes a semiconductor memory cell having a transistor, wherein the transistor includes: (1) a first semiconductor region including impurities to provide a first conductivity type (for example, a source region); (2) a second semiconductor region including impurities to provide the first conductivity type (for example, a drain region); (3) a body region disposed between the first region, the second region and the non-conducting region or layer of the substrate, wherein the body region is electrically floating and includes impurities to provide a second conductivity type wherein the second conductivity type is different from the first conductivity type; and (4) a gate spaced apart from, and capacitively coupled to, the body region. In addition, the body region includes semiconductor material that is mechanically strained.

The semiconductor memory cell includes: (1) a first data state which corresponds to a first charge in the body region of the transistor of the memory cell, and (2) a second data state which corresponds to a second charge in the body region of the transistor of the memory cell.

In one embodiment of this aspect of the inventions, at least a significant portion of the semiconductor material of the first semiconductor region is mechanically strained. In another embodiment, at least a significant portion of the semiconductor material of the first semiconductor region and the semiconductor material of the second semiconductor region are mechanically strained.

The integrated circuit may include circuitry including a plurality of transistors. Each transistor of the circuitry includes a first semiconductor region, a second semiconductor region and a body region wherein the semiconductor material of the body region of each transistor of the circuitry is mechanically strained. In one embodiment, each transistor of the plurality of transistors include a first semiconductor region, a second semiconductor region and a body region wherein the semiconductor material of the first semiconductor region, the second semiconductor region and the body region of each transistor of the circuitry are mechanically strained. Indeed, the first semiconductor region, a second semiconductor region and a body region of the transistors of the circuit may not be mechanically strained.

In another aspect, the present inventions are directed to an integrated circuit (for example, a logic or discrete memory device) having a plurality of semiconductor memory cells. The integrated circuit is disposed in or on a semiconductor region or layer which resides on or above a non-conducting region or layer of a substrate (for example, a semiconductor-on-insulator substrate or a bulk-type substrate). The plurality of semiconductor memory cells arranged in a matrix of rows and columns, each semiconductor memory cell includes a transistor. The transistor includes: (1) a first semiconductor region including impurities to provide a first conductivity type (for example, a source region); (2) a second semiconductor region including impurities to provide the first conductivity type (for example, a drain region); (3) a body region disposed between the first region, the second region and the non-conducting region or layer of the substrate, wherein the body region is electrically floating and includes impurities to provide a second conductivity type wherein the second conductivity type is different from the first conductivity type; and (4) a gate spaced apart from, and capacitively coupled to, the body region. In addition, the body region includes semiconductor material that is mechanically strained.

In addition, each semiconductor memory cell includes: (1) a first data state which corresponds to a first charge in the body region of the transistor of the memory cell, and (2) a second data state which corresponds to a second charge in the body region of the transistor of the memory cell.

In one embodiment, the semiconductor material (whether a significant portion or all) of the first semiconductor region of each memory cell is mechanically strained. In another embodiment, the semiconductor material of the first semiconductor region and the semiconductor material of the second semiconductor region of each memory cell are mechanically strained. Notably, the semiconductor material (whether a significant portion or all) of the first semiconductor region and the semiconductor material of the second semiconductor region of each memory cell may not be mechanically strained.

The integrated circuit may further include logic circuitry including a plurality of transistors having a first semiconductor region, a second semiconductor region and a body region wherein the semiconductor material of the body region is mechanically strained. In one embodiment, the semiconductor material of the first semiconductor region, the second semiconductor region and the body region of each of the plurality of transistors of the logic circuitry may be mechanically strained. Indeed, in another embodiment, the semiconductor materials of first region and the body region of each of the plurality of transistors of the logic circuitry are mechanically strained.

The integrated circuit may include peripheral circuitry including a plurality of transistors having a first semiconductor region, a second semiconductor region and a body region wherein the semiconductor material of the body region is mechanically strained. In one embodiment, the semiconductor material of the first semiconductor region, the second semiconductor region and the body region of each of the plurality of transistors of the peripheral circuitry may be mechanically strained. Indeed, in another embodiment, the semiconductor materials of first region and the body region of each of the plurality of transistors of the peripheral circuitry are mechanically strained.

Again, there are many inventions, and aspects of the inventions, described and illustrated herein. This Summary of the Inventions is not exhaustive of the scope of the present inventions. Moreover, this Summary of the Inventions is not intended to be limiting of the inventions and should not be interpreted in that manner. While certain embodiments have been described and/or outlined in this Summary of the Inventions, it should be understood that the present inventions are not limited to such embodiments, description and/or outline, nor are the claims limited in such a manner. Indeed, many other embodiments, which may be different from and/or similar to, the embodiments presented in this Summary, will be apparent from the description, illustrations and claims, which follow. In addition, although various features, attributes and advantages have been described in this Summary of the Inventions and/or are apparent in light thereof, it should be understood that such features, attributes and advantages are not required whether in one, some or all of the embodiments of the present inventions and, indeed, need not be present in any of the embodiments of the present inventions.

### BRIEF DESCRIPTION OF THE DRAWINGS

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, materials and/or elements, other than those specifically shown, are contemplated and are within the scope of the present inventions.

Moreover, there are many inventions described and illustrated herein. The present inventions are neither limited to any single aspect nor embodiment thereof, nor to any combinations and/or permutations of such aspects and/or embodiments. Moreover, each of the aspects of the present inventions, and/or embodiments thereof, may be employed alone or in combination with one or more of the other aspects of the present inventions and/or embodiments thereof. For the sake of brevity, many of those permutations and combinations will not be discussed separately herein.

FIG. 1A is a schematic representation of a prior art DRAM array including a plurality of memory cells comprised of one electrically floating body transistor;

FIG. 1B is a three-dimensional view of an exemplary prior art memory cell comprised of one electrically floating body partially depleted transistor (PD-SOI NMOS);

FIG. 1C is a cross-sectional view of the prior art memory cell of FIG. 1B, cross-sectioned along line C-C′;

FIGS. 2A and 2B are exemplary schematic illustrations of the charge relationship, for a given data state, of the electrically floating body, source and drain regions of a prior art memory cell comprised of one electrically floating body transistor (PD-SOI NMOS);

FIGS. 3A and 3B are exemplary schematic and general illustrations of conventional methods to program a memory cell to logic state “1” (i.e., generate or provide an excess of majority carrier in the electrically floating body of the transistor (an N-type channel transistor in this exemplary embodiment) of the memory cell of FIG. 1B; majority carriers in these exemplary embodiments are generated or provided by the channel electron impact ionization (FIG. 3A) and by GIDL or band to band tunneling (FIG. 3B);

FIGS. 4A-4C are exemplary schematics and general illustrations of conventional methods to program a memory cell to logic state “0” (i.e., provide relatively fewer majority carrier by removing majority carriers from the electrically floating body of the transistor of the memory cell of FIG. 1B; majority carriers may be removed through the drain region/terminal of the transistor (FIG. 4A), the source region/terminal of the transistor (FIG. 4B), and through both drain and source regions/terminals of the transistor via using the back gate pulses applied to the substrate/backside terminal of the transistor of the memory cell (FIG. 4C);

FIG. 5 illustrates an exemplary schematic (and control signal voltage relationship) of an exemplary embodiment of an aspect of the '118 Application of programming a memory cell to logic state “1” by generating, storing and/or providing an excess of majority carriers in the electrically floating body of the transistor of the memory cell;

FIG. 6 illustrates an exemplary schematic (and control signals) of an exemplary embodiment of an aspect of the '118 Application of programming a memory cell to a logic state “0” by generating, storing and/or providing relatively fewer majority carriers (as compared to the number of majority carriers in the electrically floating body of the memory cell that is programmed to a logic state “1”) in the electrically floating body of the transistor of the memory cell, wherein the majority carriers are removed (write “0”) through both drain and source terminals by applying a control signal (for example, a programming pulse) to the gate of the transistor of the memory cell;

FIG. 7 illustrates an exemplary schematic (and control signals) of an exemplary embodiment of an aspect of the '118 Application of holding or maintaining the data state of a memory cell;

FIG. 8 illustrates an exemplary schematic (and control signals) of an exemplary embodiment of an aspect of the '118 Application of reading the data state of a memory cell by sensing the amount of the current provided/generated in response to an application of a predetermined voltage on the gate of the transistor of the memory cell;

FIG. 9A is an exemplary schematic illustration of the introduction of a local mechanical stress or strain (stress or strain are herein collectively referred to as “strain”) either compressive or tensile in the floating body region of the transistor of the memory cell;

FIGS. 9B-9F are exemplary schematic illustrations of the introduction of a global mechanical strain compressive and/or tensile in: (i) the source region, the electrically floating body region and the drain region of the transistor of the memory cell (FIG. 9B), (ii) the electrically floating body region and the source region of the transistor of the memory cell (FIG. 9C), (iii) the electrically floating body region and the drain region of the transistor of the memory cell (FIG. 9D), (iv) a portion of the electrically floating body region and a portion of the source region of the transistor of the memory cell (FIG. 9E), and (v) a portion of the electrically floating body region and a portion of the drain region of the transistor of the memory cell (FIG. 9F);

FIG. 10 is a simulation of the mobility enhancement obtained between the source region and the drain region of the transistor when a tensile force is applied to the electrically floating body region, source region and the drain region of the transistor of the memory cell;

FIG. 11 represents read current waveforms of the logic states “1” and “0” for a transistor of a memory cell having a strained electrically floating body region (represented by the solid line) and a transistor having a relaxed electrically floating body region (represented by the dashed line); the programming window of the memory cell comprised of the transistor having a strained floating body region (i.e., programming window 38) is larger than the programming window of the memory cell comprised of the transistor having a relaxed floating body region (i.e., programming window 40);

FIG. 12 is an exemplary schematic illustration of the programming window improvement by the introduction of strain in the floating body region of the transistor; notably, the reading current improvement factor “F” depends, at least in part, on the strain strength;

FIG. 13A is an exemplary schematic illustration of the compressive mechanical strain introduced in the floating body region of the transistor;

FIG. 13B is an exemplary schematic illustration of the tensile mechanical strain introduced in the floating body region of the transistor of the memory cell;

FIGS. 14A-14D are schematic block diagram illustrations of exemplary integrated circuit devices in which the memory cell array (and certain peripheral circuitry) may be implemented, according to certain aspects of the present inventions, wherein FIGS. 14A and 14C are logic devices (having logic circuitry and resident memory) and FIGS. 14B and 14D are memory devices (having primarily of a memory array); and

FIG. 15 is a schematic block diagram of an embodiment of an integrated circuit device including, among other things, a memory cell array, data sense and write circuitry, memory cell selection and control circuitry, according certain aspects of the present inventions.

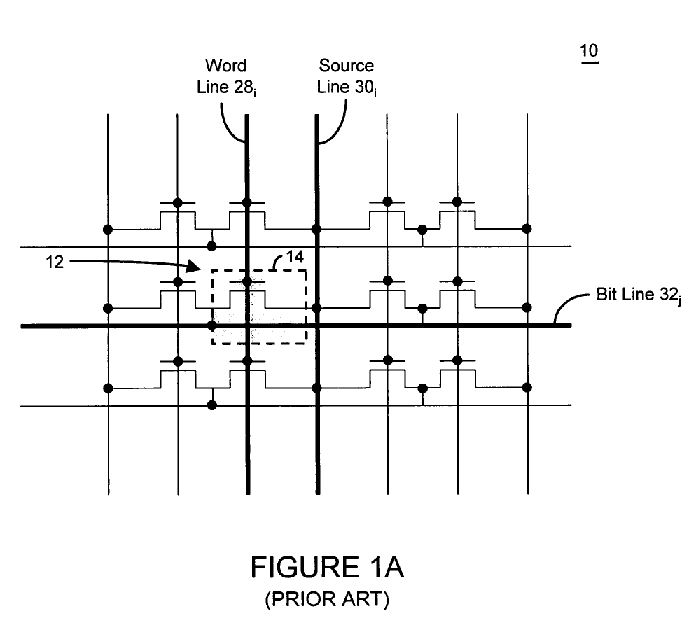

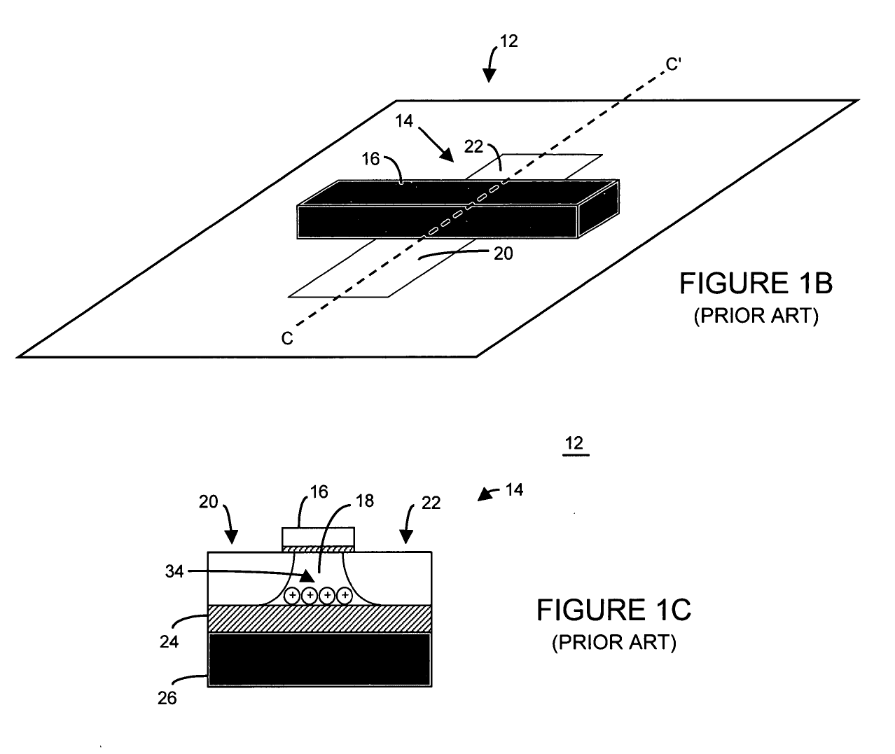

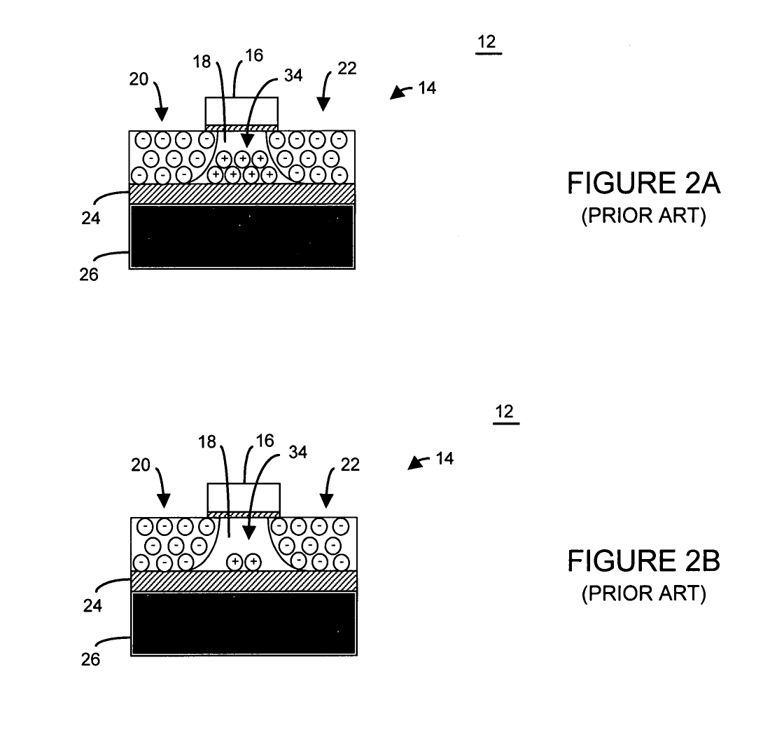

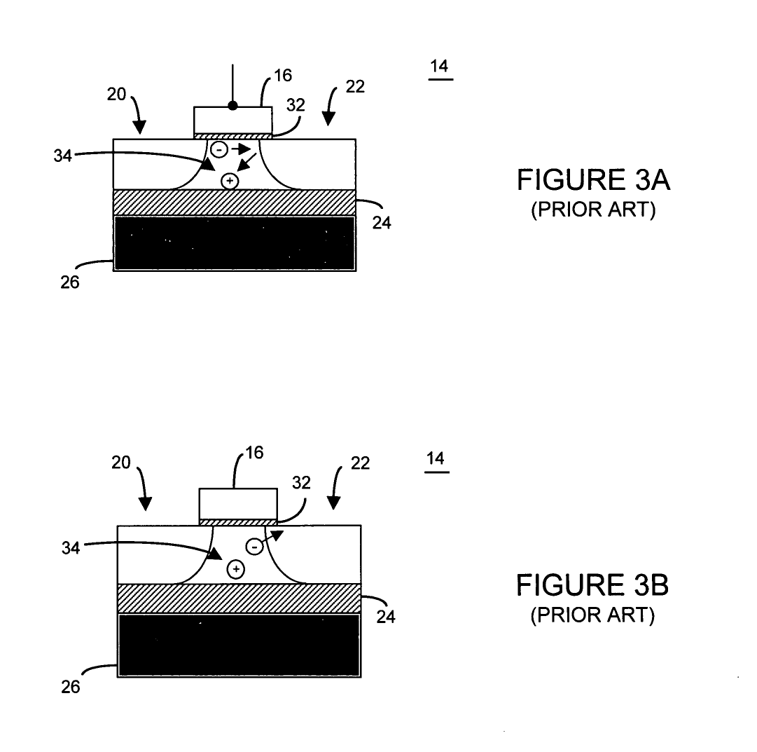

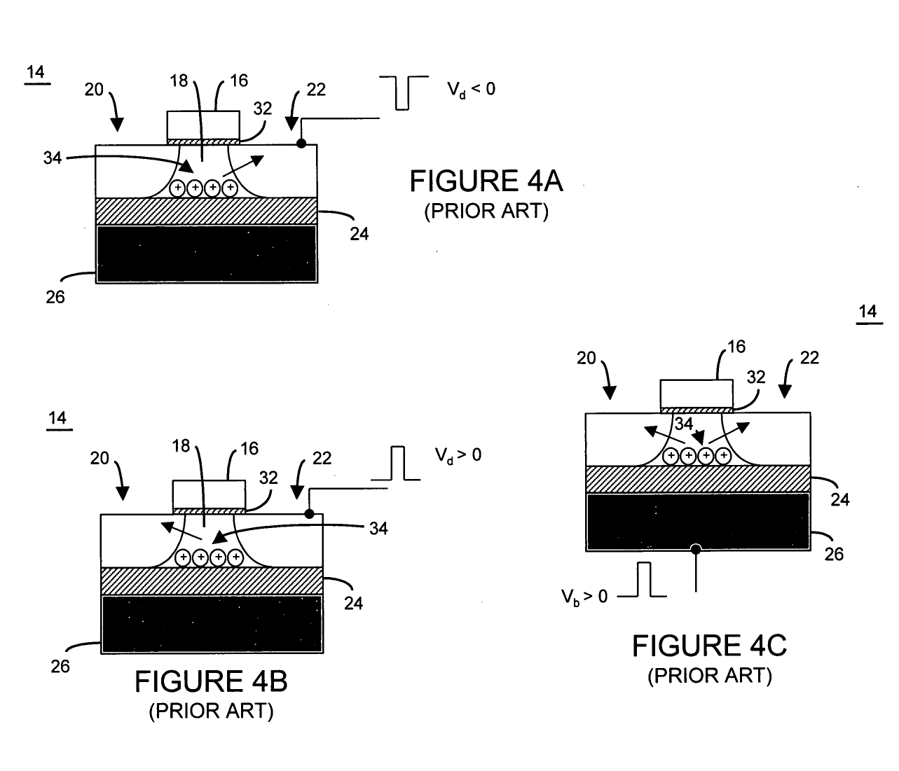

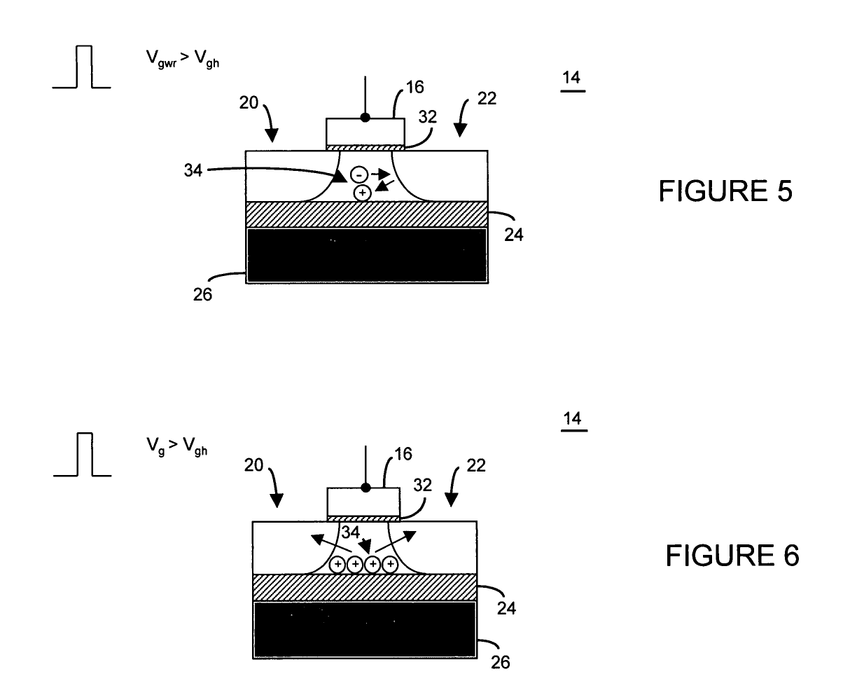

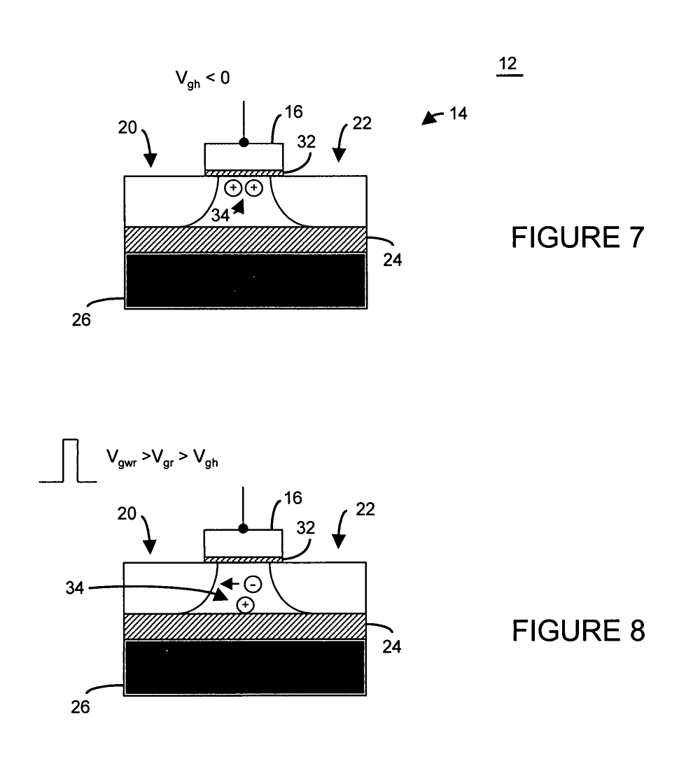

### DETAILED DESCRIPTION

At the outset, it should be noted that there are many inventions described herein as well as many aspects and embodiments of those inventions. In one aspect, the present inventions are directed to a memory cell comprising a transistor having (i) an electrically floating body region and (ii) semiconductor source, drain and/or body regions that are “locally” or “globally” under mechanical strain (for example, strain introduced via tensile or compressive forces). The present inventions are also directed to a semiconductor memory cell array having a plurality of memory cells, each comprising a transistor including (i) an electrically floating body region and (ii) semiconductor source, drain and body regions that are “locally” or “globally” under mechanical strain. Notably, the memory cell and/or memory cell array may comprise a portion of an integrated circuit device, for example, logic device (such as, a microcontroller or microprocessor) or a portion of a memory device (such as, a discrete memory).

In another aspect, the present inventions are directed to techniques for enhancing the read or programming window (i.e., enhance the read current difference between State “1” and State “0”) of a memory cell comprising (i) an electrically floating body region and (ii) semiconductor source, drain and/or body regions that are “locally” or “globally” under mechanical strain (for example, strain introduced via tensile or compressive forces). Notably, the difference in the reading currents between State “1” and State “0” is often called the “programming window” of the memory cell considered and is generally described by a current difference Δl between State “1” and State “0”.

Accordingly, the present inventions, in one aspect, describe the use of mechanically straining the semiconductor material of the electrically floating body region of the transistor to improve the programming window of the memory cell. This memory cell (and/or memory cell array) may be programmed, read and/or controlled using techniques, whether now known or later developed. For example, the memory cell (and/or memory cell array) may be programmed, read and/or controlled using techniques described and illustrated in the '662 Patent and/or the '118 Application. Indeed, any programming, reading and/or controlling techniques, whether now known or later developed, are intended to fall within the scope of the present inventions.

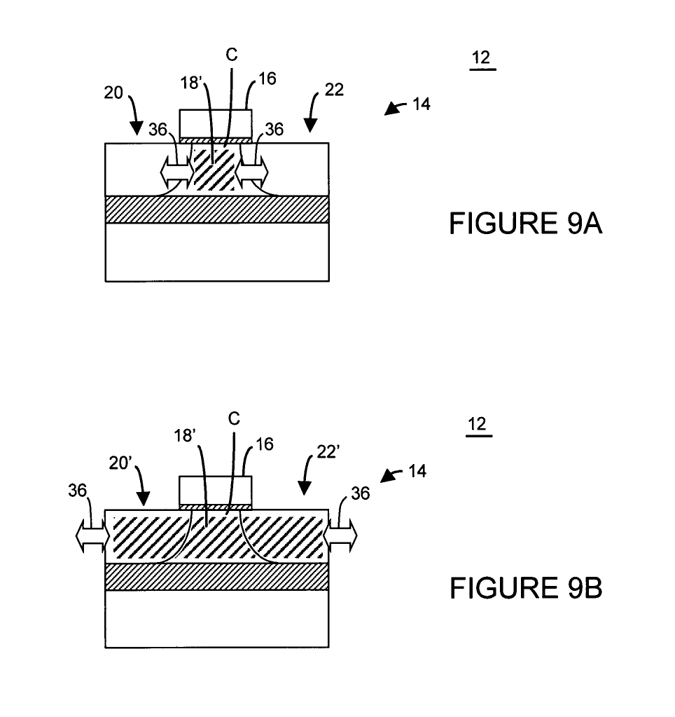

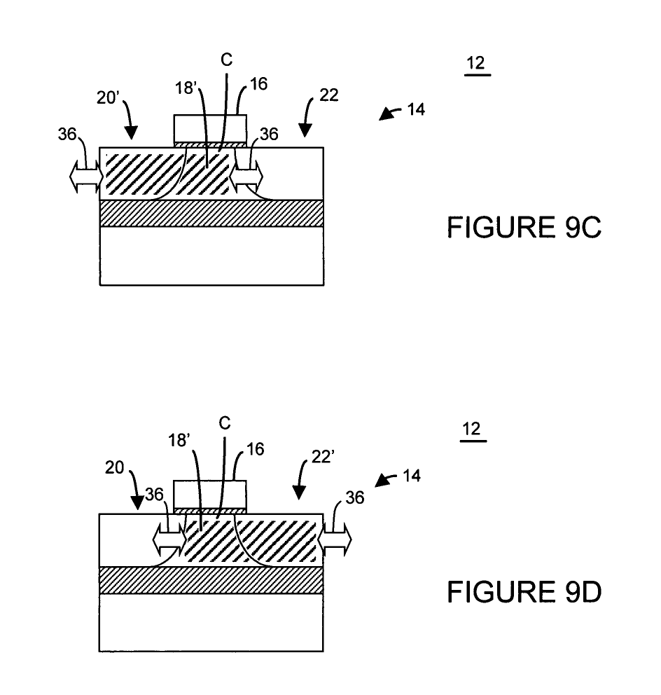

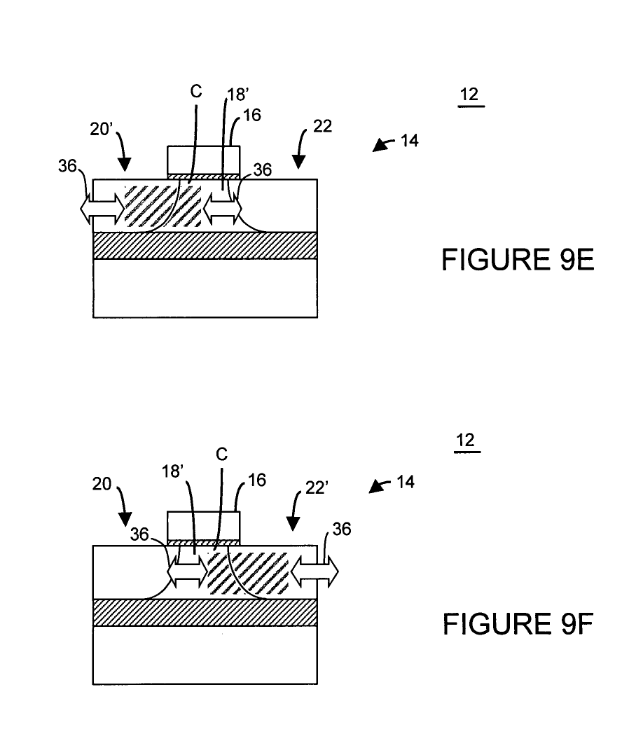

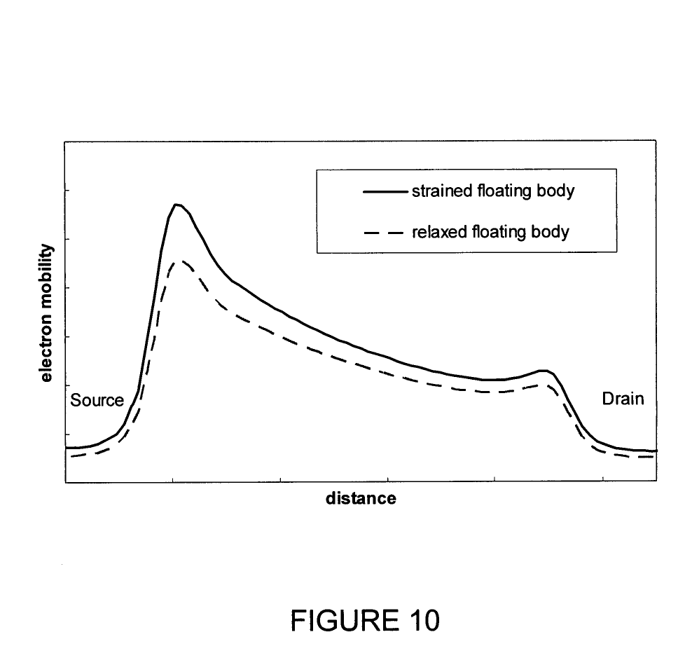

With reference to FIGS. 9A, 9B and 10, transistor 14 may include strain 36 primarily in electrically floating body region 18′ (FIG. 9A, local or localized type strain), and/or strain 36 in electrically floating body region 18′ and at least a portion of one or more of source region 20′ and/or drain region 22′ (FIGS. 9B-9F, global or globalized strain). Where semiconductor material comprising electrically floating body region 18′ is strained (whether tensile/compressive, local/global), strain 36 introduced in electrically floating body region 18′ of transistor 14 of memory cell 12 induces a carrier mobility enhancement along the semiconductor region of channel “C” of transistor 14. (See, for example, FIG. 10). Notably, mechanical strain 36 introduced into semiconductor material may be tensile and/or compressive.

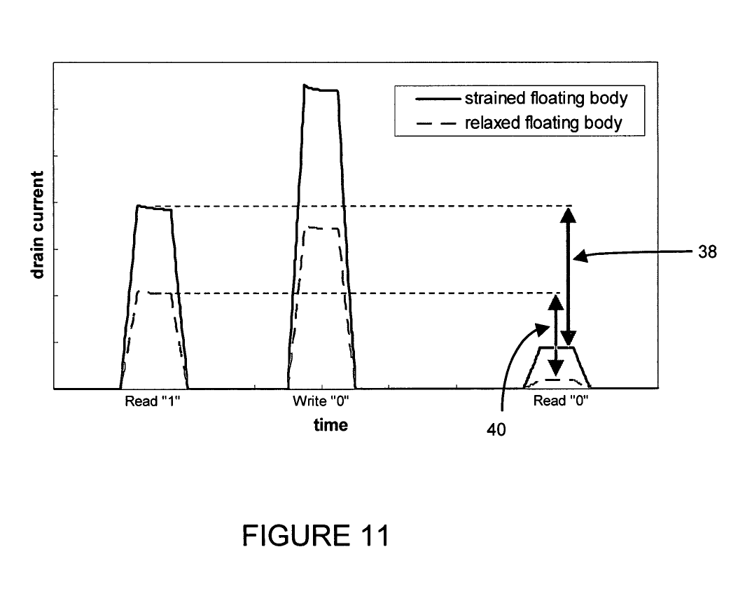

The mobility enhancement may be at least responsible for the enhancement in the programming window for memory cell 12 which includes transistor 14 having a strained electrically floating body region 18′ (for example, the semiconductor material of electrically floating body region 18′ of transistor 14 is under strain or has been strained) and the increase of the read currents of memory cell 12 including such transistor 14. In this regard, with reference to FIG. 11, the read current of memory cell 12 having strained electrically floating body region 18′ is larger than transistor 14 having an electrically floating body semiconductor region which is not strained. As such, the programming window 38 of memory cell 12 having transistor 14 with a strained electrically floating body region 18′ is larger than the programming window 40 of the memory cell including a transistor fabricated in, on or from a semiconductor material having little to no strain in the electrically floating body region.

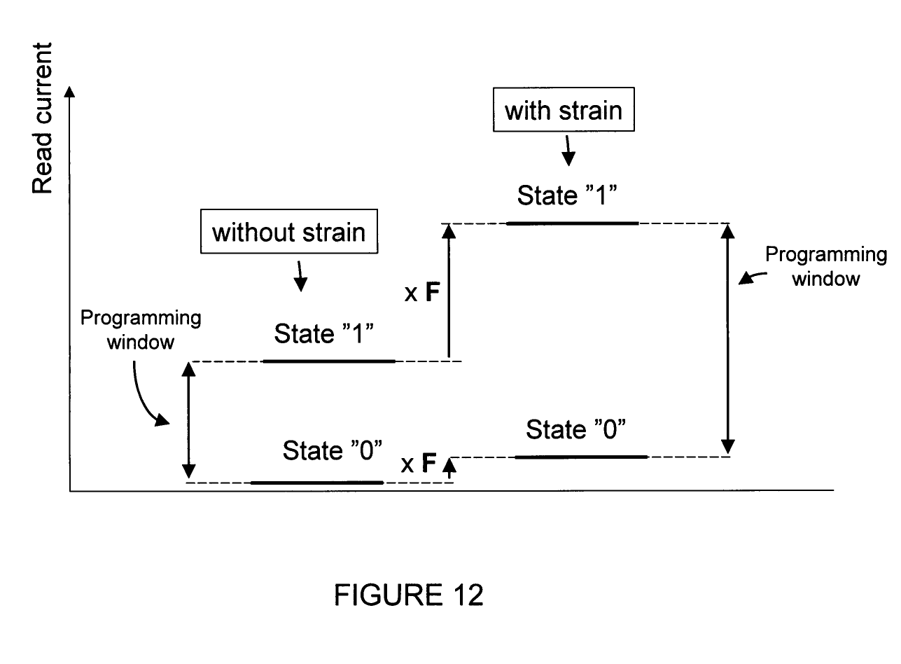

With reference to FIG. 12, the read currents for State “1” and State “0” of the memory cell having a transistor with the strained electrically floating body region may be characterized as being multiplied by the factor F in relation to the memory cell having the transistor with a relaxed electrically floating body region. As such, the relation in the programming window is also enhanced by factor F. The factor F depends on the “strength” or degree of the strain introduced in electrically floating body region of the transistor. With continued reference to FIG. 12, the read current of the state “0” in a conventional reading mode may be very close to zero with the transistor used in the sub threshold mode. For the memory cell described in the '118 Application, the read current of the State “0” may be equal to l_{off} current.

As noted above, there are many techniques to introduce a mechanical strain in the floating body region, including “local” (see, FIG. 9A), wherein only electrically floating body region 18′ is mechanically strained, or “global” (see, FIGS. 9B-9F) wherein all or substantially all of the active regions (i.e., electrically floating body region 18′ and at least one of source region 20′ and drain region 22′) are under mechanical strain. Any and all combinations of employing mechanical strain of the semiconductor of active regions 18′/18, 20′/20 and 22′/22 are intended to fall within the scope of the present inventions.

The semiconductor material of each of electrically floating body region 18/18′, source region 20/20′ and drain region 22/22′ may be appropriately doped, counter-doped and/or provided with impurities (such as, for example, phosphorus, arsenic, antimony and/or boron) to provide a suitable conductivity and/or conductivity type. For example, where transistor 14 is an N-type channel device, source region 20/20′ and drain region 22/22′ are provided with an N-type conductivity and electrically floating body region 18/18′ is provided with a P-type conductivity. Where transistor 14 is an P-type channel device, the source region 20/20′ and drain region 22/22′ are provided with a P-type conductivity and electrically floating body region 18/18′ is provided with an N-type conductivity.

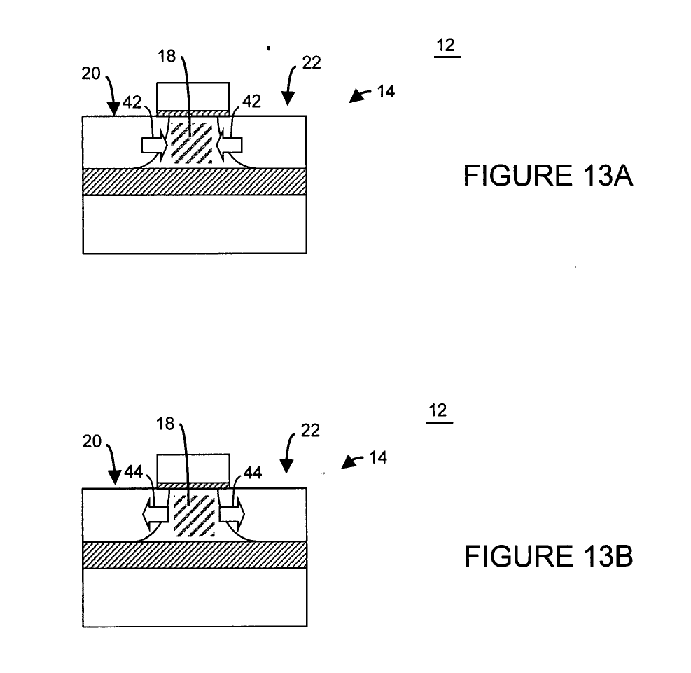

The introduced mechanical strain may be tensile and/or compressive. With reference to FIGS. 13A and 13B, strain 36 may be compressive 42 or tensile 44. In both ways, the programming window may be improved due to the modification of the mobility of the carriers used to read the data state of memory cell 12. These carriers are either electrons (N-channel transistor) or holes (P-channel transistor).

Notably, all techniques for introducing a mechanical stress or strain (as noted above, stress or strain are herein collectively referred to as “strain”) into transistor 14 (including electrically floating body region 18′), whether now known or later developed, are intended to fall within the scope of the present inventions. For example, different ways to introduce strain (local or global) are described and illustrated in a review article published by C. Mazuré and A.-J. Auberton-Hervé in the Proceedings of ESSDERC 2005 Conference, page 27, which is incorporated herein by reference. (See Exhibit A of U.S. Provisional Application Ser. No. 60/728,060).

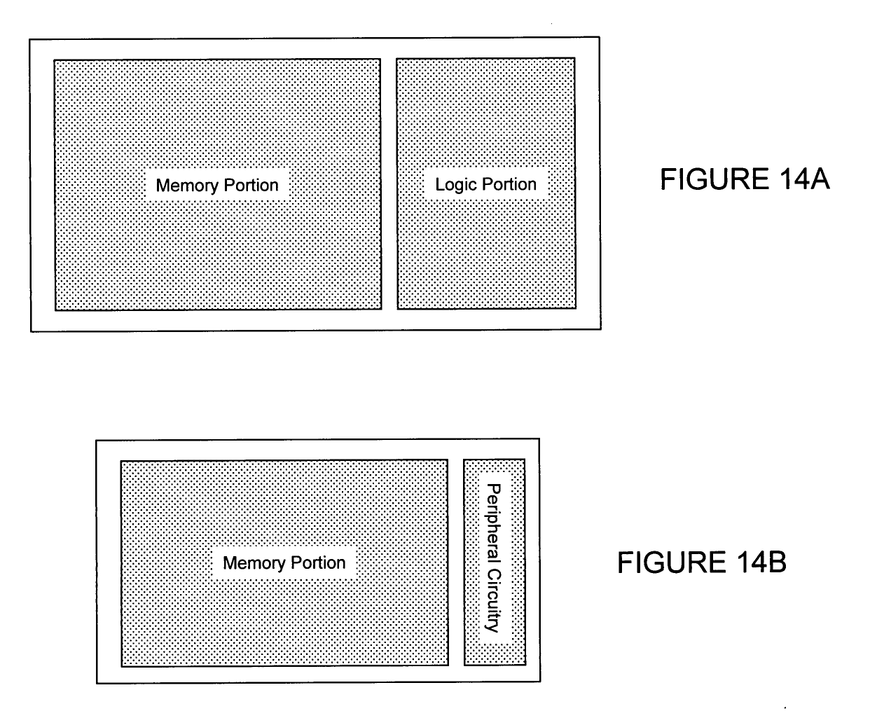

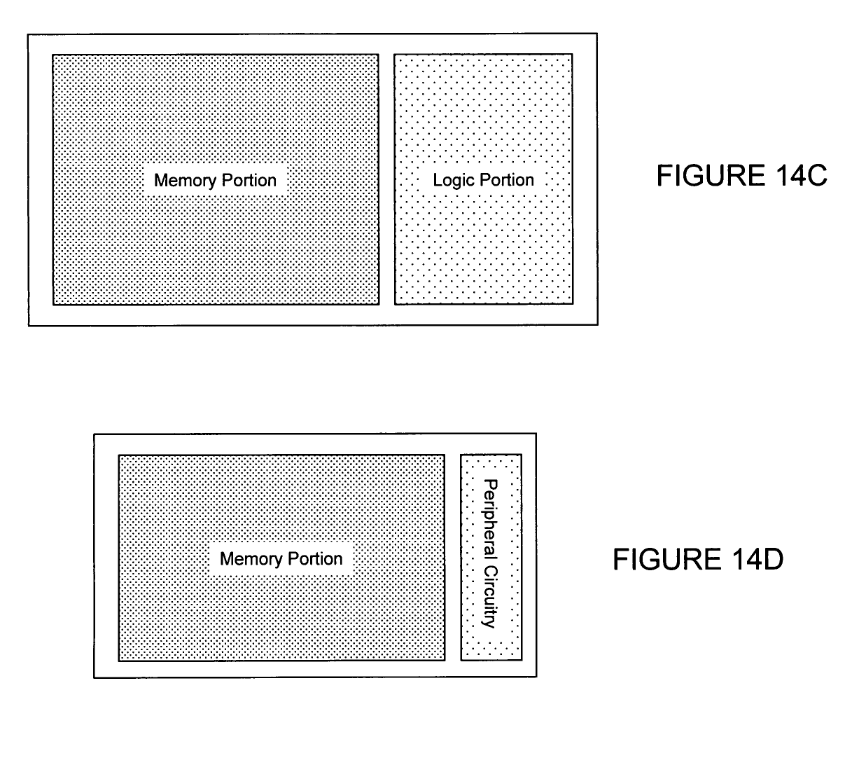

As mentioned above, memory cells 12 (having a transistor 14 including mechanically strained electrically floating body region 18′) and memory cell array 10 (including a plurality of such memory cells 12) of the present inventions may be implemented in an integrated circuit device having a memory portion and a logic portion (see, for example, FIGS. 14A and 14C), or an integrated circuit device that is primarily a memory device (see, for example, FIGS. 14B and 14D). Indeed, the present inventions may be implemented in any device having one or more memory cells 12 (having a transistor 14 including mechanically strained electrically floating body region 18′) and/or memory cell arrays 10. The transistors 14 of memory cells 12 may include local strain (see, FIG. 9A) or global strain (see, FIGS. 9B-9D).

Further, the integrated circuit device may include a memory portion and a logic portion comprising transistors 14 fabricated in, on or from a semiconductor material which includes local or global strain (see, FIGS. 14A and 14B). The integrated circuit device may also include (i) a memory portion comprising transistors 14 fabricated in, on and/or from a semiconductor material which is locally or globally strained and (ii) a logic portion having transistors fabricated in, on and/or from a semiconductor material which includes little to no mechanical strain (see, FIGS. 14C and 14D).

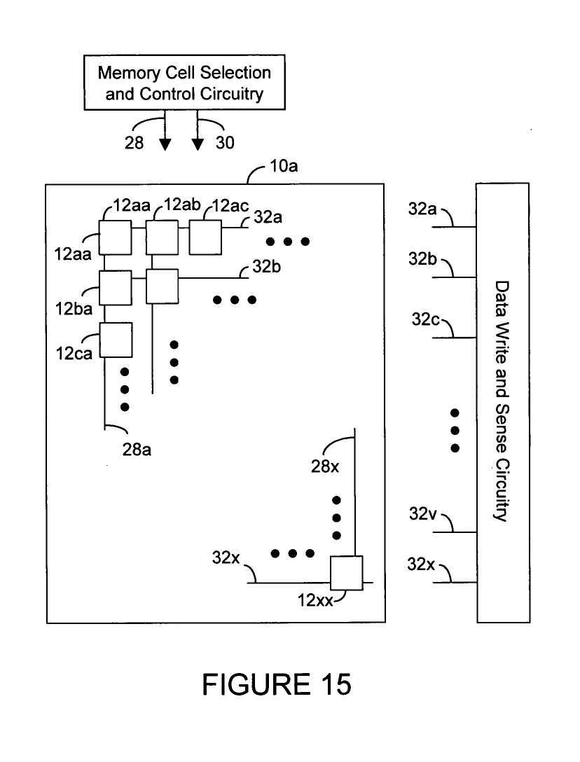

With reference to FIG. 15, an integrated circuit device may include array 10, having a plurality of memory cells 12 (wherein each memory cell 12 includes a transistor 14 having mechanically strained electrically floating body region 18′), data write and sense circuitry, and memory cell selection and control circuitry (not illustrated in detail). The data write and sense circuitry writes data into and senses the data state of one or more memory cells. The memory cell selection and control circuitry selects and/or enables one or more predetermined memory cells 12 to be read by data sense circuitry during a read operation.

Notably, the present inventions may be employed in any memory cell architecture having an electrically floating body region, and/or memory cell array architecture, layout, structure and/or configuration employing such electrically floating body memory cells. In this regard, a transistor having an electrically floating body region, which employs the structure, materials and/or techniques of the present inventions, may be implemented in the memory cell, architecture, layout, structure and/or configuration described and illustrated in the following non-provisional U.S. patent applications:

(1) application Ser. No. 10/450,238, which was filed by Fazan et al. on Jun. 10, 2003 and entitled “Semiconductor Device” (now U.S. Pat. No. 6,969,662);

(2) application Ser. No. 10/487,157, which was filed by Fazan et al. on Feb. 18, 2004 and entitled “Semiconductor Device” (U.S. Patent Application Publication No. 2004/0238890);

(3) application Ser. No. 10/829,877, which was filed by Ferrant et al. on Apr. 22, 2004 and entitled “Semiconductor Memory Cell, Array, Architecture and Device, and Method of Operating Same” (U.S. Patent Application Publication No. 2005/0013163);

(4) application Ser. No. 10/840,009, which was filed by Ferrant et al. on May 6, 2004 and entitled “Semiconductor Memory Device and Method of Operating Same” (U.S. Patent Application Publication No. 2004/0228168);

(5) application Ser. No. 10/941,692, which was filed by Fazan et al. on Sep. 15, 2004 and entitled “Low Power Programming Technique for a One Transistor SOI Memory Device & Asymmetrical Electrically Floating Body Memory Device, and Method of Manufacturing Same” (U.S. Patent Application Publication No. 2005/0063224);

(6) application Ser. No. 11/304,387, which was filed by Okhonin et al. on Dec. 15, 2004 and entitled “Bipolar Reading Technique for a Memory Cell Having an Electrically Floating Body Transistor” (U.S. Patent Application Publication No. 2006/0131650);

(7) application Ser. No. 11/453,594, which was filed by Okhonin et al. on Dec. 15, 2004 and entitled “Low Power Programming Technique for a Floating Body Memory Transistor, Memory Cell, and Memory Array”;

(8) U.S. Non-Provisional patent application Ser. No. 11/509,188, filed on Aug. 24, 2006, and entitled “Memory Cell and Memory Cell Array Having an Electrically Floating Body Transistor, and Methods of Operating Same” (referred to above); and

(9) U.S. Non-Provisional Patent Application Ser. No. 11/515,667, which was filed by Bauser on Sep. 5, 2006, and entitled “Method and Circuitry to Generate a Reference Current for Reading a Memory Cell, and Device Implementing Same”.

The entire contents of these nine (9) U.S. patent applications, including, for example, the inventions, features, attributes, architectures, configurations, materials, techniques and advantages described and illustrated therein, are incorporated by reference herein. For the sake of brevity, those discussions will not be repeated; rather those discussions (text and illustrations), including the discussions relating to the memory cell, architecture, layout, structure, are incorporated by reference herein in its entirety.

Notably, the memory cells (having one or more transistors each including a strained electrically floating body region) may be controlled (for example, programmed or read) using any of the control circuitry described and illustrated in the above-referenced nine (9) U.S. patent applications. For the sake of brevity, those discussions will not be repeated and is incorporated herein by reference. Indeed, all memory cell selection and control circuitry, and technique for programming, reading, controlling and/or operating memory cells including transistors having strained electrically floating body regions, whether now known or later developed, are intended to fall within the scope of the present inventions.

Moreover, the data write and data sense circuitry may include a sense amplifier (not illustrated in detail herein) to read the data stored in memory cells 12. The sense amplifier may sense the data state stored in memory cell 12 using voltage or current sensing circuitry and/or techniques. In the context of a current sense amplifier, the current sense amplifier may compare the cell current to a reference current, for example, the current of a reference cell (not illustrated). From that comparison, it may be determined whether memory cell 12 contained logic high (relatively more majority carriers 34 contained within body region 18) or logic low data state (relatively less majority carriers 34 contained within body region 18). Such circuitry and configurations thereof are well known in the art.

The electrically floating memory cells, transistors and/or memory array(s) may be fabricated using well known techniques and/or materials. Indeed, any fabrication technique and/or material, whether now known or later developed, may be employed to fabricate the strained electrically floating body transistors, memory cells, and/or memory array(s). For example, the present inventions may employ strained silicon, germanium, silicon/germanium, gallium arsenide or any other strained semiconductor material (whether bulk-type or SOI) in which transistors may be formed. As such, the electrically floating memory cells may be disposed on or in (collectively “on”) SOI-type substrate or a bulk-type substrate.

Indeed, the electrically floating transistors, memory cells, and/or memory array(s) may employ the techniques described and illustrated in non-provisional patent application entitled “Integrated Circuit Device, and Method of Fabricating Same”, which was filed on Jul. 2, 2004, by Fazan, Ser. No. 10/884,481 (U.S. Patent Application Publication No. 2005/0017240). The contents of the '481 Application are incorporated by reference herein.

Moreover, memory array 10 (including SOI memory transistors) may be integrated with SOI logic transistors, as described and illustrated in the Integrated Circuit Device Patent Applications. For example, in one embodiment, an integrated circuit device includes memory section (having, for example, PD or FD SOI memory transistors 14) and logic section (having, for example, high performance transistors, such as FinFET, multiple gate transistors, and/or non-high performance transistors (for example, single gate transistors that do not possess the performance characteristics of high performance transistors—not illustrated)).

Further, memory array(s) 10 may be comprised of N-channel, P-channel and/or both types of transistors, as well as partially depleted and/or fully depleted type transistors. For example, circuitry that is peripheral to the memory array (for example, sense amplifiers or comparators, row and column address decoders, as well as line drivers (not illustrated herein)) may include fully depleted type transistors (whether P-channel and/or N-channel type). Alternatively, such circuitry may include partially depleted type transistors (whether P-channel and/or N-channel type). There are many techniques to integrate both partially depleted and/or fully depleted type transistors on the same substrate (see, for example, application Ser. No. 10/487,157, which was filed by Fazan et al. on Feb. 18, 2004 and entitled “Semiconductor Device” (U.S. Patent Application Publication No. 2004/0238890)). All such techniques, whether now known or later developed, are intended to fall within the scope of the present inventions.

Notably, electrically floating body transistor 14 may be a symmetrical or non-symmetrical device. Where transistor 14 is symmetrical, the source and drain regions are essentially interchangeable. However, where transistor 14 is a non-symmetrical device, the source or drain regions of transistor 14 have different electrical, physical, doping concentration and/or doping profile characteristics. As such, the source or drain regions of a non-symmetrical device are typically not interchangeable. This notwithstanding, the drain region of the electrically floating N-channel transistor of the memory cell (whether the source and drain regions are interchangeable or not) is that region of the transistor that is connected to the bit line/sense amplifier.

As mentioned above, the memory arrays may be comprised of N-channel, P-channel and/or both types of transistors. Indeed, circuitry that is peripheral to the memory array (for example, sense amplifiers or comparators, row and column address decoders, as well as line drivers (not illustrated herein)) may include P-channel and/or N-channel type transistors. Where P-channel type transistors are employed as memory cells 12 in the memory array(s), suitable write and read voltages (for example, negative voltages) are well known to those skilled in the art in light of this disclosure. Accordingly, for sake of brevity, these discussions will not be repeated.

There are many inventions described and illustrated herein. While certain embodiments, features, attributes and advantages of the inventions have been described and illustrated, it should be understood that many others, as well as different and/or similar embodiments, features, attributes and advantages of the present inventions, are apparent from the description and illustrations. As such, the embodiments, features, attributes and advantages of the inventions described and illustrated herein are not exhaustive and it should be understood that such other, similar, as well as different, embodiments, features, attributes and advantages of the present inventions are within the scope of the present inventions.

With the memory cell and operating technique presented herein, the improvement in the programming window may facilitate simplification of the circuit architecture to read the data state of the memory cell. For example, the sense amplifier architecture may also be simplified and therefore may be more robust to the variations inherent to the fabrication process (for example mismatch).

Moreover, the above embodiments of the present inventions are merely exemplary embodiments. They are not intended to be exhaustive or to limit the inventions to the precise forms, techniques, materials and/or configurations disclosed. Many modifications and variations are possible in light of the above teaching. It is to be understood that other embodiments may be utilized and operational changes may be made without departing from the scope of the present inventions. As such, the foregoing description of the exemplary embodiments of the inventions has been presented for the purposes of illustration and description. Many modifications and variations are possible in light of the above teaching. It is intended that the scope of the inventions not be limited solely to the description above.

What is claimed is:

1. An integrated circuit, disposed in or on a semiconductor region or layer which resides on or above a non-conducting region or layer of a substrate, the integrated circuit comprising:
a semiconductor memory cell including a transistor, wherein the transistor includes:
a first semiconductor region including impurities to provide a first conductivity type;
a second semiconductor region including impurities to provide the first conductivity type;
a body region disposed between the first region, the second region and the non-conducting region or layer of the substrate, wherein the body region is electrically floating and includes impurities to provide a second conductivity type wherein the second conductivity type is different from the first conductivity type;
a gate spaced apart from, and capacitively coupled to, the body region,
wherein the semiconductor memory cell includes (1) a first data state which corresponds to a first charge in the body region of the transistor of the memory cell, and (2) a second data state which corresponds to a second charge in the body region of the transistor of the memory cell; and
wherein the body region includes semiconductor material that is mechanically strained.

2. The integrated circuit of claim 1 wherein the semiconductor material of the first semiconductor region is mechanically strained.

3. The integrated circuit of claim 1 wherein the semiconductor material of the first semiconductor region and the semiconductor material of the second semiconductor region are mechanically strained.

4. The integrated circuit of claim 1 wherein the semiconductor material of the first semiconductor region and the semiconductor material of the second semiconductor region are not mechanically strained.

5. The integrated circuit of claim 1 further includes circuitry including a plurality of transistors each transistor having a first semiconductor region, a second semiconductor region and a body region wherein the semiconductor material of the body region of each transistor of the circuitry is mechanically strained.

6. The integrated circuit of claim 1 further includes circuitry including a plurality of transistors each transistor having a first semiconductor region, a second semiconductor region and a body region wherein the semiconductor material of the first semiconductor region, the second semiconductor region and the body region of each transistor of the circuitry are mechanically strained.

7. The integrated circuit of claim 1 further includes circuitry including a plurality of transistors each transistor having a first semiconductor region, a second semiconductor region and a body region wherein the semiconductor material of the body region of each transistor of the circuitry is not mechanically strained.

8. The integrated circuit of claim 1 wherein the integrated circuit is disposed in or on a semiconductor-on-insulator substrate.

9. The integrated circuit of claim 1 wherein the integrated circuit is disposed in or on a bulk-type substrate.

10. An integrated circuit, disposed in or on a semiconductor region or layer which resides on or above a non-conducting region or layer of a substrate, the integrated circuit comprising:
a plurality of semiconductor memory cells arranged in a matrix of rows and columns, each semiconductor memory cell includes a transistor including:
a first semiconductor region having impurities to provide a first conductivity type;
a second semiconductor region having impurities to provide the first conductivity type;
a body region disposed between the first region, the second region and the non-conducting region or layer of the substrate, wherein the body region is electrically floating and includes impurities to provide a second conductivity type wherein the second conductivity type is different from the first conductivity type;
a gate spaced apart from, and capacitively coupled to, the body region,
wherein each semiconductor memory cell includes (1) a first data state which corresponds to a first charge in the body region of the transistor of the memory cell, and (2) a second data state which corresponds to a second charge in the body region of the transistor of the memory cell; and
wherein the body region of each memory cell includes semiconductor material that is mechanically strained.

11. The integrated circuit of claim 10 wherein the semiconductor material of the first semiconductor region of each memory cell is mechanically strained.

12. The integrated circuit of claim 10 wherein the semiconductor material of the first semiconductor region and the semiconductor material of the second semiconductor region of each memory cell are mechanically strained.

13. The integrated circuit of claim 10 wherein the semiconductor material of the first semiconductor region and the semiconductor material of the second semiconductor region of each memory cell are not mechanically strained.

14. The integrated circuit of claim 10 further includes logic circuitry including a plurality of transistors having a first semiconductor region, a second semiconductor region and a body region wherein only the semiconductor material of the body region of each transistor of the plurality of transistors of the logic circuitry is mechanically strained.

15. The integrated circuit of claim 10 further includes logic circuitry including a plurality of transistors having a first semiconductor region, a second semiconductor region and a body region wherein the semiconductor material of the first semiconductor region, the second semiconductor region and the body region of each of the plurality of transistors of the logic circuitry are mechanically strained.

16. The integrated circuit of claim 10 further includes logic circuitry including a plurality of transistors having a first semiconductor region, a second semiconductor region and a body region wherein the semiconductor materials of first region and the body region of each of the plurality of transistors of the logic circuitry are mechanically strained.

17. The integrated circuit of claim 10 further includes peripheral circuitry to read, write and/or control the plurality of semiconductor memory cells, wherein the peripheral circuitry includes a plurality of transistors having a first semiconductor region, a second semiconductor region and a body region wherein only the semiconductor material of the body region each transistor of the plurality of transistors of the logic circuitry is mechanically strained.

18. The integrated circuit of claim 10 further includes peripheral circuitry to read, write and/or control the plurality of semiconductor memory cells, wherein the peripheral circuitry includes a plurality of transistors having a first semiconductor region, a second semiconductor region and a body region wherein the semiconductor material of the first semiconductor region, the second semiconductor region and the body region of each of the plurality of transistors of the peripheral circuitry are mechanically strained.

19. The integrated circuit of claim 10 further includes peripheral circuitry to read, write and/or control the plurality of semiconductor memory cells, wherein the peripheral circuitry includes a plurality of transistors having a first semiconductor region, a second semiconductor region and a body region wherein the semiconductor materials of first region and the body region of each of the plurality of transistors of the peripheral circuitry are mechanically strained.

20. The integrated circuit of claim 10 wherein the integrated circuit is disposed in or on (i) a semiconductor-on-insulator substrate or (ii) a bulk-type substrate.
